(19) United States
(12) Patent Application Publication
(10) Pub. No.: US 2025/0334461 A1
(43) Pub. Date: Oct. 30, 2025

(54) ELECTRONIC DEVICE

(71) Applicant: Murata Manufacturing Co., Ltd., Nagaokakyo-shi, Kyoto-fu (JP)

(72) Inventors: Hiroaki KITADA, Nagaokakyo-shi, Kyoto-fu (JP); Hidekazu KANO, Nagaokakyo-shi, Kyoto-fu (JP)

(21) Appl. No.: 18/790,214

(22) Filed: Jul. 31, 2024

Related U.S. Application Data
(63) Continuation of application No. PCT/JP2023/004158, filed on Feb. 8, 2023.

(30) Foreign Application Priority Data
Feb. 10, 2022 (JP) 2022-019248

(51) Int. Cl. G01L 1/16; G06F 1/16; G06F 3/041

(52) U.S. Cl. CPC G01L 1/16; G06F 1/1629; G06F 3/0414

(57) ABSTRACT

An electronic device that includes: a housing; a first plate-shaped member that has a first upper main surface and a first lower main surface that are arranged in a vertical direction, and is fixed to the housing such that a part of a body of a user or an operation member is capable of contacting the first upper main surface; a sensor that detects deformation of the first plate-shaped member; and a first adhesive member in at least a part of a region surrounding the first plate-shaped member as viewed in the vertical direction and which fixes the first lower main surface of the first plate-shaped member to the housing. The first adhesive member has a storage elastic modulus of 1 MPa to 20 MPa.

### CROSS REFERENCE TO RELATED APPLICATIONS

The present application is a continuation of International application No. PCT/JP2023/004158, filed Feb. 8, 2023, which claims priority to Japanese Patent Application No. 2022-019248, filed Feb. 10, 2022, the entire contents of each of which are incorporated herein by reference.

### TECHNICAL FIELD

The present disclosure relates to an electronic device including a plate-shaped member and a sensor.

### BACKGROUND ART

As an disclosure related to a conventional electronic device, for example, a pressing sensor described in Patent Document 1 is known. The pressing sensor includes an operation surface, a plate-shaped member, and a piezoelectric film. A user performs a pressing operation by touching the operation surface. The plate-shaped member becomes bent by the pressing operation. The piezoelectric film is bonded to the plate-shaped member to be bent together with the plate-shaped member. As a result, a pressing force is detected by the output of the piezoelectric film.
Patent Document 1: WO 2015/083678

### SUMMARY OF THE DISCLOSURE

By the way, there is a demand for accurately detecting, by the pressing sensor described in Patent Document 1, the magnitude of a force with which a user presses the operation surface.

Therefore, an object of the present disclosure is to provide an electronic device capable of accurately detecting the magnitude of a force with which a user presses a plate-shaped member.

An electronic device according to an embodiment of the present disclosure includes: a housing; a first plate-shaped member that has a first upper main surface and a first lower main surface that are arranged in a vertical direction, and is fixed to the housing such that a part of a body of a user or an operation member is capable of contacting the first upper main surface; a sensor that detects deformation of the first plate-shaped member; and a first adhesive member in at least a part of a region surrounding the first plate-shaped member as viewed in the vertical direction and which fixes the first lower main surface of the first plate-shaped member to the housing, in which the first adhesive member has a storage elastic modulus of 1 MPa to 20 MPa.

According to the electronic device of the present disclosure, the magnitude of a force with which a user presses the plate-shaped member can be accurately detected.

### BRIEF EXPLANATION OF THE DRAWINGS

FIG. 1 is an exploded perspective view of an electronic device 1.

FIG. 2 is a sectional view of the electronic device 1 taken along line A-A.

FIG. 3 is a bottom view and a sectional view of a sensor 6.

FIG. 4 is a diagram illustrating an example of an amount of deformation of a first plate-shaped member 2 of an electronic device according to a comparative example.

FIG. 5 is a diagram illustrating an example of amounts of stretching and contraction of the first plate-shaped member 2 of the electronic device according to the comparative example in a right-left direction and an example of amounts of stretching and contraction of the first plate-shaped member 2 of the electronic device according to the comparative example in a front-rear direction.

FIG. 6 is a diagram illustrating an example of an amount of deformation of the first plate-shaped member 2 of the electronic device according to the comparative example.

FIG. 7 is a diagram illustrating an example of amounts of stretching and contraction of the first plate-shaped member 2 of the electronic device according to the comparative example in the right-left direction and an example of amounts of stretching and contraction of the first plate-shaped member 2 of the electronic device according to the comparative example in the front-rear direction.

FIG. 8 is a graph illustrating a relationship between a storage elastic modulus of a second adhesive member 5, a storage elastic modulus of a first adhesive member 7, and whether or not a NULL point occurs.

FIG. 9 is a diagram illustrating an example of an amount of deformation of a first plate-shaped member 2 of the electronic device 1 in the right-left direction.

FIG. 10 is a diagram illustrating an example of amounts of stretching and contraction of the first plate-shaped member 2 of the electronic device 1 in the right-left direction and an example of amounts of stretching and contraction of the first plate-shaped member 2 of the electronic device 1 in the front-rear direction.

### DESCRIPTION OF THE PREFERRED EMBODIMENTS

### Embodiments

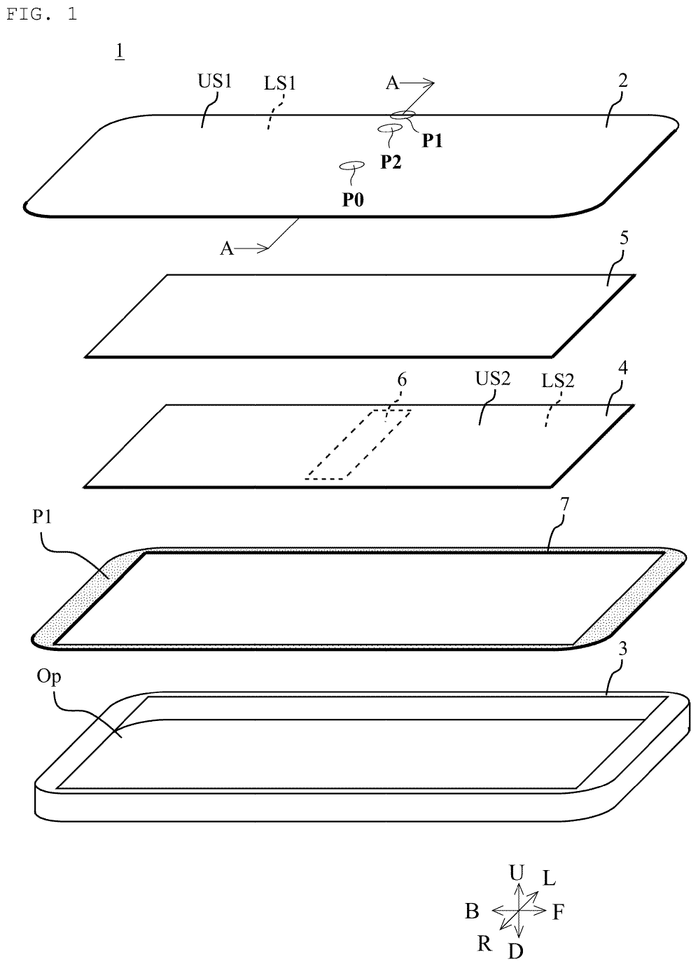

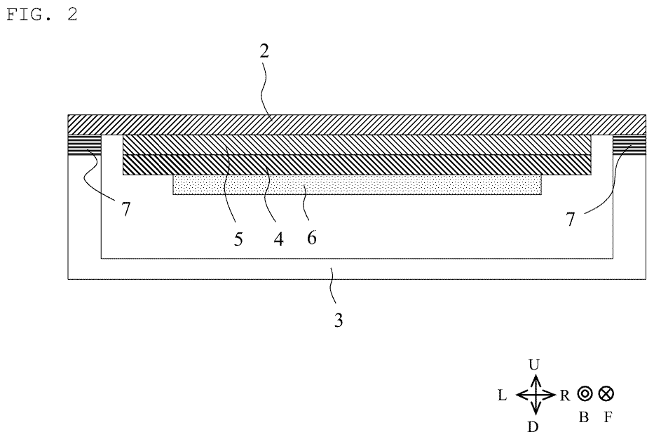

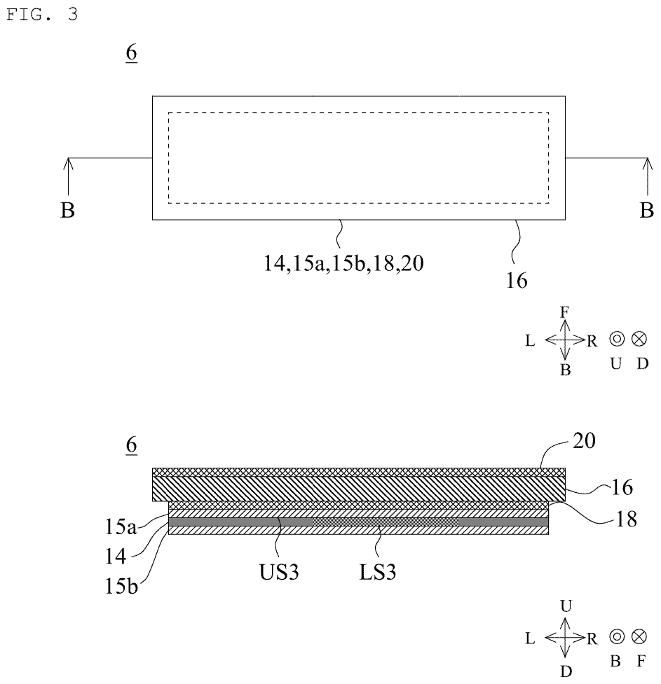

Hereinafter, a configuration of an electronic device 1 according to an embodiment of the present disclosure will be described with reference to the drawings. FIG. 1 is an exploded perspective view of the electronic device 1. FIG. 2 is a sectional view of the electronic device 1 taken along line A-A. FIG. 3 is a bottom view and a cross-sectional view of a sensor 6.

In the present specification, directions are defined as follows. In the electronic device 1, a direction in which a first upper main surface US1 and a first lower main surface LS1 of a first plate-shaped member 2 are arranged is defined as a vertical direction. As viewed in the vertical direction, a direction in which a long side of the first plate-shaped member 2 of the electronic device 1 extends is defined as a front-rear direction. As viewed in the vertical direction, a direction in which a short side of the first plate-shaped member 2 of the electronic device 1 extends is defined as a right-left direction. The vertical direction, the right-left direction, and the front-rear direction are orthogonal to each other. Note that the definition of directions in the present description is an example. Therefore, directions at the time of actual use of the electronic device 1 do not need to coincide with the directions in the present specification. Further, the vertical direction may be reversed in FIG. 1. The right-left direction may be reversed in FIG. 1. The front-rear direction may be reversed in FIG. 1.

The electronic device 1 is a portable electronic terminal such as a smartphone or a tablet computer. As illustrated in FIGS. 1 and 2, the electronic device 1 includes the first plate-shaped member 2, a housing 3, a second plate-shaped member 4, a second adhesive member 5, the sensor 6, and a first adhesive member 7.

As illustrated in FIG. 1, the first plate-shaped member 2 has the first upper main surface US1 and the first lower main surface LS1 that are arranged in the vertical direction. The first plate-shaped member 2 has a rectangular shape having two long sides extending in the front-rear direction and two short sides extending in the right-left direction as viewed in the vertical direction. A part of a body of a user or an operation member comes into contact with the first upper main surface US1 of the first plate-shaped member 2. In the present embodiment, the first plate-shaped member 2 is a transparent plate. The material of the first plate-shaped member 2 is, for example, glass.

As illustrated in FIG. 1, the second plate-shaped member 4 has a second upper main surface US2 and a second lower main surface LS2 that are arranged in the vertical direction. The second plate-shaped member 4 has a rectangular shape having two long sides extending in the front-rear direction and two short sides extending in the right-left direction as viewed in the vertical direction. The second plate-shaped member 4 is fixed to the first lower main surface LS1 of the first plate-shaped member 2. The second plate-shaped member 4 is fixed to the first plate-shaped member 2 by the second adhesive member 5 to be described later. The entire second plate-shaped member 4 overlaps the first plate-shaped member 2 as viewed in the vertical direction. The second plate-shaped member 4 does not protrude from the outer edge of the first plate-shaped member 2 as viewed in the vertical direction. The second plate-shaped member 4 is, for example, an organic EL display or a liquid crystal display. The second plate-shaped member 4 may include a touch panel for detecting a position where the user touches the first plate-shaped member 2. However, the touch panel may be included in the first plate-shaped member 2.

The second adhesive member 5 fixes the second plate-shaped member 4 to the first plate-shaped member 2. More specifically, as illustrated in FIG. 2, the second adhesive member 5 fixes the second upper main surface US2 of the second plate-shaped member 4 to the first lower main surface LS1 of the first plate-shaped member 2. The material of the second adhesive member 5 is, for example, a double-sided tape, a thermosetting adhesive, a thermoplastic adhesive, or an ultraviolet (UV) cured adhesive.

As illustrated in FIG. 1, the housing 3 is located below the first plate-shaped member 2. The housing 3 is a box. The housing 3 has a rectangular shape as viewed in the vertical direction. A long side of the housing 3 extends in the front-rear direction. A short side of the housing 3 extends in the right-left direction. The outer edge of the housing 3 viewed in the vertical direction coincides with the outer edge of the first plate-shaped member 2 viewed in the vertical direction. An upper face of the housing 3 is open. The opening Op of the housing 3 has a rectangular shape as viewed in the vertical direction.

The first adhesive member 7 fixes the first plate-shaped member 2 to the housing 3. More specifically, the first adhesive member 7 fixes the first lower main surface LS1 of the first plate-shaped member 2 to the housing 3. That is, the first plate-shaped member 2 is fixed to the housing 3. The first adhesive member 7 is disposed in at least a part of a region surrounding the first plate-shaped member 2 as viewed in the vertical direction. The first adhesive member 7 overlaps at least one of the two long sides of the first plate-shaped member 2 as viewed in the vertical direction. In the present embodiment, as illustrated in FIG. 1, the first adhesive member 7 is disposed in the vicinity of the outer edge of the first plate-shaped member 2 as viewed in the vertical direction. That is, as illustrated in FIG. 1, the first adhesive member 7 has a rectangular frame shape surrounding the first plate-shaped member 2 as viewed in the vertical direction. Therefore, the first adhesive member 7 has an annular shape surrounding the periphery of the first plate-shaped member 2 as viewed in the vertical direction. As illustrated in FIG. 1, the first adhesive member 7 overlaps each of the two long sides of the first plate-shaped member 2 and each of the two short sides of the first plate-shaped member 2 as viewed in the vertical direction. Thus, the first adhesive member 7 fixes the periphery of the opening Op of the housing 3 and the vicinity of the outer edge of the first plate-shaped member 2. The first adhesive member 7 as described above has waterproofness. In addition, when the electronic device 1 collides with a floor or the like due to falling, the first adhesive member 7 absorbs an impact applied to the first plate-shaped member 2 and suppresses damage to the first plate-shaped member 2.

The sensor 6 detects deformation of the first plate-shaped member 2. The sensor 6 is fixed to the first lower main surface LS1 of the first plate-shaped member 2. In the present specification, “the sensor 6 is fixed to the first lower main surface LS1 of the first plate-shaped member 2.” means that the sensor 6 may be directly fixed to the first lower main surface LS1 of the first plate-shaped member 2, or the sensor 6 may be fixed to another member fixed to the first lower main surface LS1 of the first plate-shaped member 2. In the present embodiment, as illustrated in FIG. 1, the sensor 6 is fixed to the second lower main surface LS2 of the second plate-shaped member 4. The sensor 6 has a rectangular shape as viewed in the vertical direction. The sensor 6 has a longitudinal direction extending in the right-left direction. The sensor 6 is located at the center of the first plate-shaped member 2 in the front-rear direction and the right-left direction as viewed in the vertical direction. In the above arrangement, an electric charge generated by the piezoelectric film 14 to be described later is mainly due to stretching and contraction of the piezoelectric film 14 in the right-left direction. As a result, for example, a length of the sensor 6 in the lateral direction of the sensor 6 may be 10 mm or less, and the ratio (aspect ratio) of a length of the sensor 6 in the right-left direction (longitudinal direction) to the length of the sensor 6 in the front-rear direction (lateral direction) may be 3 to 10.

When the first plate-shaped member 2 becomes bent downward due to the pressing of the first plate-shaped member 2 by the user, the second plate-shaped member 4 also becomes bent downward. Then, the sensor 6 becomes bent downward together with the second plate-shaped member 4. As a result, the sensor 6 outputs a detection signal corresponding to the deformation that has occurred in the first plate-shaped member 2 when the user presses the first plate-shaped member 2. Hereinafter, details of the sensor 6 will be described with reference to FIG. 3.

As illustrated in FIG. 3, the sensor 6 includes a piezoelectric film 14, an upper electrode 15a, a lower electrode 15b, a substrate 16, and an adhesive layer 18. The piezoelectric film 14 has a sheet shape. Therefore, as illustrated in FIG. 3, the piezoelectric film 14 has a third upper main surface US3 and a third lower main surface LS3 that are arranged in the vertical direction. A length of the piezoelectric film 14 in the right-left direction is longer than a length of the piezoelectric film 14 in the front-rear direction. That is, the piezoelectric film 14 has a longitudinal direction extending in the right-left direction. In the present embodiment, the piezoelectric film 14 has a rectangular shape having a long side extending in the right-left direction as viewed in the vertical direction. The piezoelectric film 14 generates an electric charge according to an amount of deformation of the piezoelectric film 14. In the present embodiment, the piezoelectric film 14 is a PLA film. The piezoelectric film 14 will be described below in more detail.

The piezoelectric film 14 has a characteristic in which the polarity of an electric charge generated when the piezoelectric film 14 is stretched in the right-left direction is opposite to the polarity of an electric charge generated when the piezoelectric film 14 is stretched in the front-rear direction. Specifically, the piezoelectric film 14 is a film formed of a chiral polymer. The chiral polymer is, for example, polylactic acid (PLA), particularly poly-L-lactic acid (PLLA). PLLA, which is a chiral polymer, has a main chain with a helical structure. PLLA has piezoelectricity in which molecules are oriented when the PLLA is uniaxially stretched. The piezoelectric film 14 has a piezoelectric constant of d14. The uniaxial stretching direction (orientation direction) of the piezoelectric film 14 forms an angle of 45 degrees with respect to each of the front-rear direction and the right-left direction. This angle of 45 degrees includes, for example, angles ranging from 45 degrees plus 10 degrees to 45 degrees minus 10 degrees. As a result, the piezoelectric film 14 generates an electric charge when the piezoelectric film 14 is stretched in the right-left direction or contracted in the right-left direction. The polarity of an electric charge generated by the piezoelectric film 14 when the piezoelectric film 14 is stretched in the right-left direction is different from the polarity of an electric charge generated by the piezoelectric film 14 when the piezoelectric film 14 is stretched in the front-rear direction. The piezoelectric film 14 generates a positive charge when the piezoelectric film 14 is stretched in the right-left direction, for example. The piezoelectric film 14 generates a negative charge when the piezoelectric film 14 is stretched in the front-rear direction, for example. The magnitude of an electric charge depends on an amount of deformation of the piezoelectric film 14 due to stretching or contraction. More precisely, the magnitude of the electric charge is proportional to a differential value of the amount of deformation of the piezoelectric film 14 due to stretching or contraction.

The upper electrode 15a is a signal electrode. The detection signal is output from the upper electrode 15a. As illustrated in FIG. 3, the upper electrode 15a is disposed on the third upper main surface US3 of the piezoelectric film 14. The lower electrode 15b is a ground electrode. The lower electrode 15b is connected to the ground. As illustrated in FIG. 3, the lower electrode 15b is disposed on the third lower main surface LS3 of the piezoelectric film 14.

As illustrated in FIG. 3, the substrate 16 is disposed on the upper electrode 15a. The substrate 16 holds the piezoelectric film 14, the upper electrode 15a, and the lower electrode 15b, and is deformed together with the piezoelectric film 14. The substrate 16 has a sheet shape. The substrate 16 has an upper main surface and a lower main surface. A length of the substrate 16 in the right-left direction is longer than a length of the substrate 16 in the front-rear direction. In the present embodiment, the substrate 16 has a rectangular shape having a long side extending in the right-left direction as viewed in the vertical direction. The long side of the substrate 16 is longer than the long side of the piezoelectric film 14, a long side of the upper electrode 15a, and a long side of the lower electrode 15b. A short side of the substrate 16 is longer than a short side of the piezoelectric film 14, a short side of the upper electrode 15a, and a short side of the lower electrode 15b. The piezoelectric film 14, the upper electrode 15a, and the lower electrode 15b are disposed in a region surrounded by the outer edge of the substrate 16 as viewed in the vertical direction. The material of the substrate 16 is, for example, polyurethane or PET. The substrate 16 may be formed of a flexible substrate or a printed wiring board. In a case where the substrate 16 is formed of a flexible substrate or a printed wiring board, the upper electrode 15a may be formed in the flexible substrate or the printed wiring board, and the piezoelectric film 14 may be fixed to the substrate 16 by the adhesive layer 18 described later.

The adhesive layer 18 fixes the piezoelectric film 14, the upper electrode 15a, and the lower electrode 15b to the substrate 16. More specifically, as illustrated in FIG. 3, the adhesive layer 18 is disposed on the lower main surface of the substrate 16. The adhesive layer 18 covers a part of the lower main surface of the substrate 16. As illustrated in FIG. 3, the adhesive layer 18 covers the entire upper main surface of the upper electrode 15a. The outer edge of the adhesive layer 18 is surrounded by the outer edge of the substrate 16 as viewed in the vertical direction. The adhesive layer 18 allows the upper electrode 15a and the substrate 16 to adhere to each other. As a result, the deformation of the substrate 16 is transmitted to the piezoelectric film 14. The material of the adhesive layer 18 is, for example, a double-sided tape, a thermosetting adhesive, or a thermoplastic adhesive.

The adhesive layer 20 is disposed on the upper main surface of the substrate 16. The adhesive layer 20 fixes the substrate 16 to the second lower main surface LS2 of the second plate-shaped member 4. The material of the adhesive layer 20 is, for example, a double-sided tape, a thermosetting adhesive, or a thermoplastic adhesive.

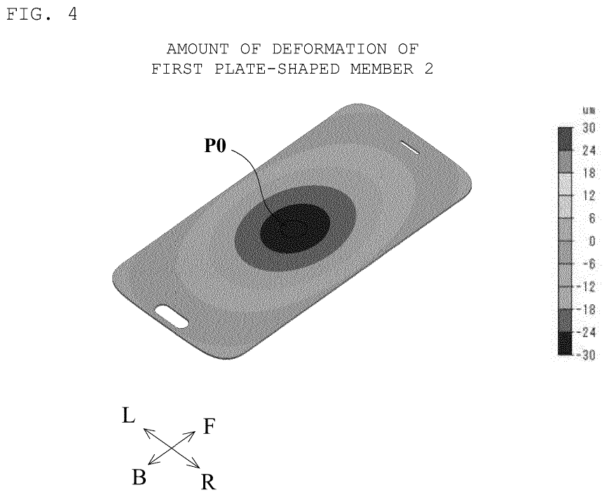

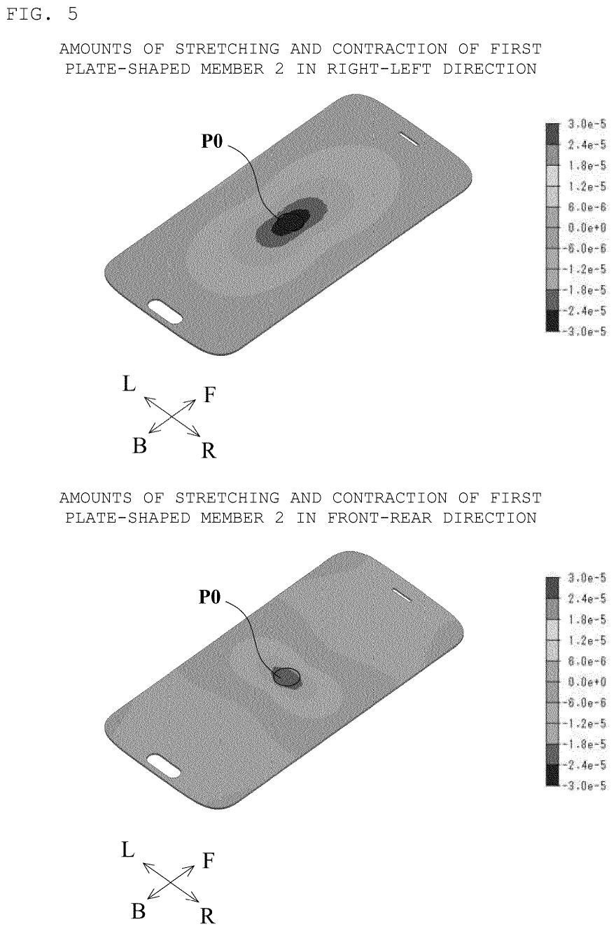

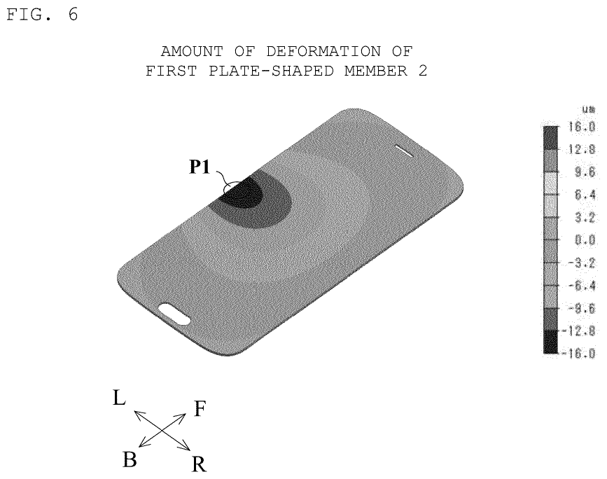

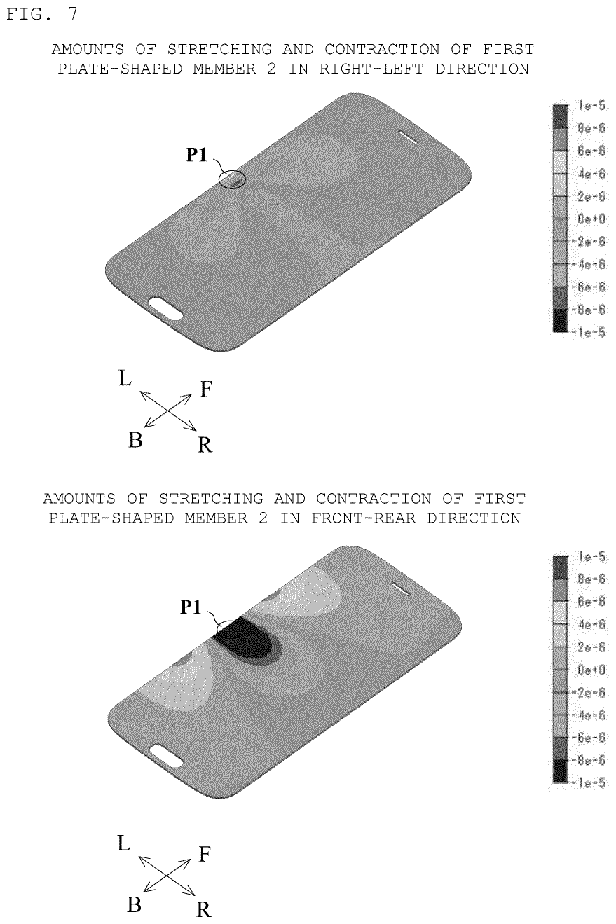

Meanwhile, the electronic device 1 has a structure capable of accurately detecting the magnitude of a force with which the user presses the first plate-shaped member 2. This structure will be described below. FIG. 4 is a diagram illustrating an example of an amount of deformation of a first plate-shaped member 2 of an electronic device according to a comparative example. FIG. 5 is a diagram illustrating an example of amounts of stretching and contraction of the first plate-shaped member 2 of the electronic device according to the comparative example in the right-left direction and an example of amounts of stretching and contraction of the first plate-shaped member 2 of the electronic device according to the comparative example in the front-rear direction. In FIGS. 4 and 5, the user pressed a position P0 downward. FIG. 6 is a diagram illustrating an example of an amount of deformation of the first plate-shaped member 2 of the electronic device according to the comparative example. FIG. 7 is a diagram illustrating an example of amounts of stretching and contraction of the first plate-shaped member 2 of the electronic device according to the comparative example in the right-left direction and an example of amounts of stretching and contraction of the first plate-shaped member 2 of the electronic device according to the comparative example in the front-rear direction. In FIGS. 6 and 7, the user pressed a position P1 downward. Note that FIGS. 4 to 7 are results of computer simulation.

First, the electronic device according to the comparative example and the electronic device 1 will be described. Hereinafter, X is a component or a member of the electronic device 1. In the present specification, the storage elastic modulus of the member X is defined as follows. The storage elastic modulus of the member X means the storage elastic modulus of the member X when the member X is contracted by 30 μm.

In the electronic device according to the comparative example, a first adhesive member 7 has a storage elastic modulus of 0.1 MPa. On the other hand, in the electronic device 1, the first adhesive member 7 has a storage elastic modulus of 1 MPa to 20 MPa.

Next, a problem of the electronic device according to the comparative example will be described. In the electronic device according to the comparative example, it is difficult to accurately detect the magnitude of a force with which the user presses the first plate-shaped member 2. When the user presses directly above the sensor 6 (position P0 in FIG. 1) downward, the position P0 of the first plate-shaped member 2 is deformed downward. At this time, as illustrated in FIG. 4, the first plate-shaped member 2 is deformed into a bowl shape centered on the position P0. More specifically, as illustrated in FIG. 5, the first plate-shaped member 2 is stretched in the right-left direction and the front-rear direction. As illustrated in FIG. 5, the first plate-shaped member 2 is stretched in the right-left direction. As illustrated in FIG. 5, the first plate-shaped member 2 is stretched in the front-rear direction. As illustrated in FIG. 5, the amount of stretching of the first plate-shaped member 2 in the right-left direction is larger than the amount of stretching of the first plate-shaped member 2 in the front-rear direction. By the above-described stretching action, the piezoelectric film 14 is also stretched in a similar manner to the first plate-shaped member 2. As a result, the amount of stretching of the piezoelectric film 14 in the right-left direction when the user presses directly above the sensor 6 (position P0 in FIG. 1) downward is larger than the amount of stretching of the piezoelectric film 14 in the front-rear direction when the user presses directly above the sensor 6 (position P0 in FIG. 1) downward.

On the other hand, when the user presses the left long side (position P1 in FIG. 1) of the first plate-shaped member 2 downward, the position P1 of the first plate-shaped member 2 is deformed downward. At this time, as illustrated in FIG. 6, the first plate-shaped member 2 is deformed around the position P1. More specifically, the first plate-shaped member 2 is stretched in the front-rear direction as illustrated in FIG. 7. On the other hand, the first plate-shaped member 2 is hardly stretched in the right-left direction. By the above-described stretching action, the piezoelectric film 14 is also stretched in a similar manner to the first plate-shaped member 2. The amount of stretching of the piezoelectric film 14 in the right-left direction when the user presses the left long side (position P1 in FIG. 1) of the first plate-shaped member 2 downward is smaller than the amount of stretching of the piezoelectric film 14 in the front-rear direction when the user presses directly above the sensor 6 (position P1 in FIG. 1) downward.

A difference between an electric charge generated by stretching the piezoelectric film 14 in the right-left direction and an electric charge generated by stretching the piezoelectric film 14 in the front-rear direction is a detection signal output from the upper electrode 15a. Therefore, when the user presses directly above sensor 6 (position P0 in FIG. 1) downward, the detection signal is positive. On the other hand, when the user presses the left long side (position P1 in FIG. 1) of the first plate-shaped member 2 downward, the detection signal is negative.

A point (position P2 in FIG. 1) at which an electric charge generated by stretching the piezoelectric film 14 in the right-left direction and an electric charge generated by stretching the piezoelectric film 14 in the front-rear direction are equal is present between the position P0 and the position P1 as viewed in the vertical direction. When the user presses the position P2 downward, the detection signal becomes zero. In the present specification, a NULL point means a point (position P2 in FIG. 1) at which the detection signal becomes 0 when an electric charge generated by stretching the piezoelectric film 14 in the right-left direction and an electric charge generated by stretching the piezoelectric film 14 in the front-rear direction become equal.

As described above, in the electronic device according to the comparative example, a NULL point at which the detection signal becomes zero occurs. Therefore, in the electronic device according to the comparative example, it is difficult to accurately detect the magnitude of a force with which the user pushes the first plate-shaped member 2.

Therefore, as a result of examination, the inventor of the present application has found that when the storage elastic modulus of the first adhesive member 7 is increased, the center of deformation of the piezoelectric film 14 viewed in the vertical direction is shifted to the right from the position P1 when the user presses the left long side (position P1 in FIG. 1) of the first plate-shaped member 2. In order to confirm this examination result, the inventor of the present application conducted the following computer simulation.

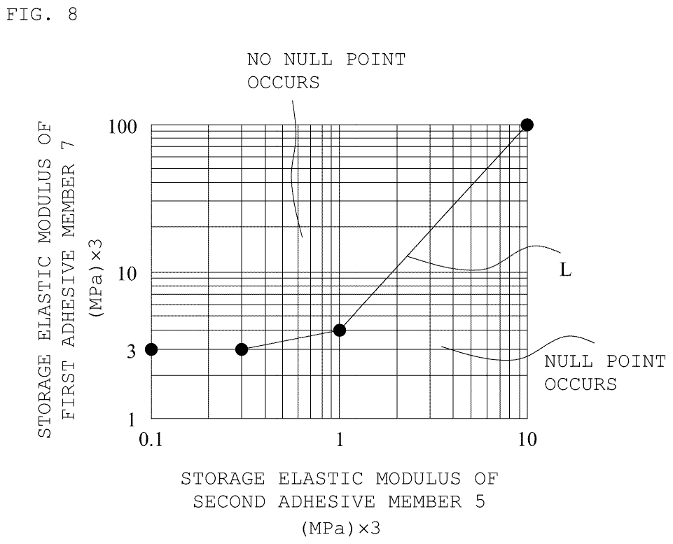

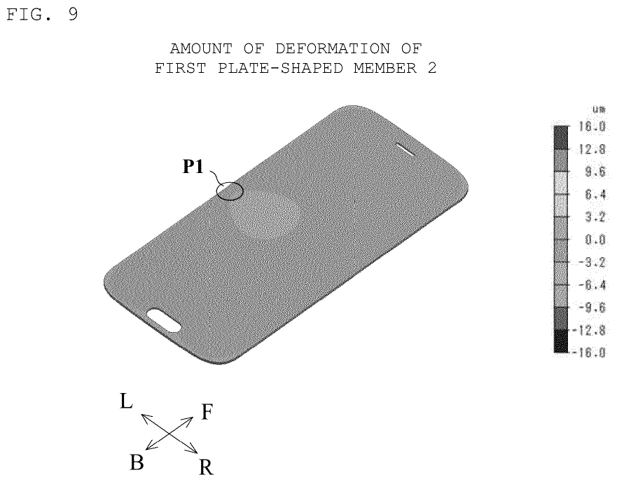

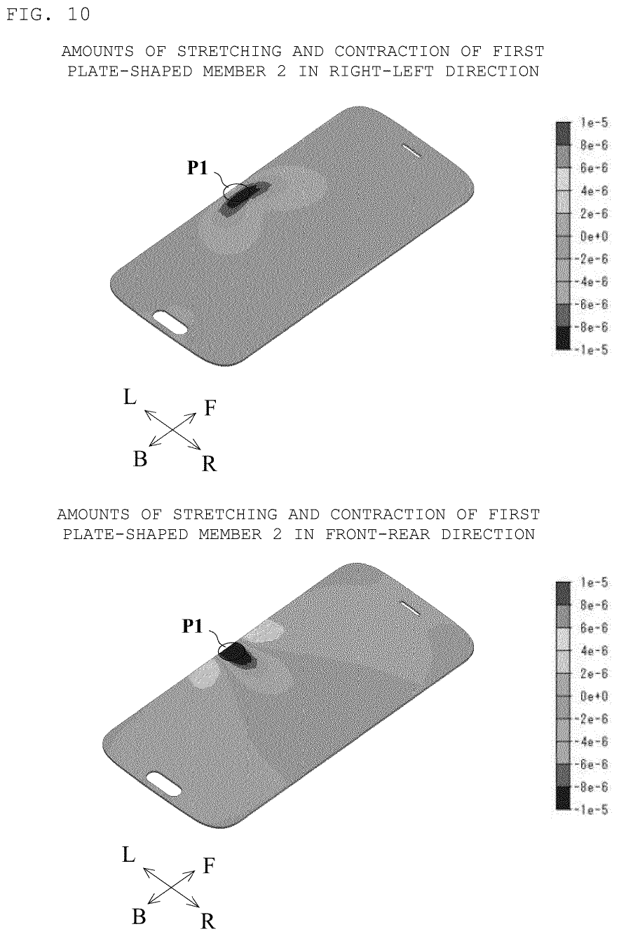

The inventor of the present application calculated whether or not a NULL point occurred when the storage elastic modulus of the second adhesive member 5 and the storage elastic modulus of the first adhesive member 7 were changed. FIG. 8 is a graph illustrating the relationship between the storage elastic modulus of the second adhesive member 5, the storage elastic modulus of the first adhesive member 7, and whether or not a NULL point occurs. The horizontal axis represents the storage elastic modulus of the second adhesive member 5. The vertical axis represents the storage elastic modulus of the first adhesive member 7. FIG. 9 is a diagram illustrating an example of an amount of deformation of the first plate-shaped member 2 of the electronic device 1 in the right-left direction. FIG. 10 is a diagram illustrating an example of amounts of stretching and contraction of the first plate-shaped member 2 of the electronic device 1 in the right-left direction and an example of amounts of stretching and contraction of the first plate-shaped member 2 of the electronic device 1 in the front-rear direction. In FIGS. 6 and 7, the user pressed a position P1 downward. In FIGS. 9 and 10, the storage elastic modulus of the first adhesive member 7 is 1 MPa.

As illustrated in FIG. 8, a line L is a boundary line on whether a NULL point occurs. Therefore, according to FIG. 8, when the storage elastic modulus of the second adhesive member 5 and the storage elastic modulus of the first adhesive member 7 are above the line L, the NULL point does not occur. On the other hand, when the storage elastic modulus of the second adhesive member 5 and the storage elastic modulus of the first adhesive member 7 are below the line L, a NULL point occurs. Therefore, as illustrated in FIG. 8, the storage elastic modulus of the first adhesive member 7 may be higher than the storage elastic modulus of the second adhesive member 5. In addition, it can be seen that when the storage elastic modulus of the first adhesive member 7 is 1 MPa to 20 MPa, a NULL point can be prevented from occurring.

As described above, the first adhesive member 7 has functions of waterproofness and impact absorption. When these functions are prioritized, the storage elastic modulus of the first adhesive member 7 is preferably low. Specifically, the storage elastic modulus of the first adhesive member 7 is desirably 5 MPa or less. As illustrated in FIG. 8, when the storage elastic modulus of the second adhesive member 5 is larger than 0 Pa and 0.3 MPa or less, the requirement of the storage elastic modulus of the first adhesive member 7 for preventing a NULL point can be relaxed to about 1 MPa. Therefore, the storage elastic modulus of the second adhesive member 5 is desirably higher than 0 Pa and 0.3 MPa or less. As a result, the storage elastic modulus of the first adhesive member 7 can be set to 5 MPa or less, and the waterproof property and the impact absorption function of the first adhesive member 7 can be secured.

As an example of a case where the NULL point does not occur, a case where the storage elastic modulus of the first adhesive member 7 is 1 MPa will be described.

When the user presses the left long side (position P1 in FIG. 1) of the first plate-shaped member 2 downward, the center of deformation of the first plate-shaped member 2 viewed in the vertical direction is shifted to the right from the position P1 as illustrated in FIG. 9. More specifically, the first plate-shaped member 2 is stretched in the right-left direction as illustrated in FIG. 7. By the above-described stretching action, the piezoelectric film 14 is also stretched in a similar manner to the first plate-shaped member 2.

On the other hand, the first plate-shaped member 2 is stretched and contracted in the front-rear direction as illustrated in FIG. 10. By the above-described stretching action, the piezoelectric film 14 is also stretched in a similar manner to the first plate-shaped member 2. It can be seen that the amount of stretching of the piezoelectric film 14 in the right-left direction when the user presses the left long side (position P1 in FIG. 1) of the first plate-shaped member 2 downward is larger than the amount of stretching of the piezoelectric film 14 in the front-rear direction when the user presses the position directly above the sensor 6 (position P1 in FIG. 1) downward.

In the electronic device 1, in a case where the user presses the left long side (position P1 in FIG. 1) of the first plate-shaped member 2 downward, the detection signal is positive. Therefore, according to the electronic device 1, a NULL point can be prevented from occurring near the left long side. As a result, the piezoelectric film 14 can output a detection signal corresponding to the deformation that has occurred in the first plate-shaped member 2. Therefore, the magnitude of a force with which the user presses the first plate-shaped member 2 can be calculated based on the detection signal output from the sensor 6. As a result, according to the electronic device 1, the magnitude of the force with which the user presses the first plate-shaped member 2 can be accurately detected.

### Other Embodiments

The electronic device 1 according to the present disclosure is not limited to the electronic device 1, and can be modified within the scope of the gist thereof.

In the electronic device 1, the piezoelectric film 14 may be a PVDF (polyvinylidene fluoride) film. Further, the piezoelectric film 14 may be piezoelectric ceramic.

The sensor 6 may include a strain sensor. More specifically, as illustrated in FIGS. 7 and 10, the amount of stretching of the piezoelectric film 14 in the right-left direction is larger than the amount of stretching of the piezoelectric film 14 in the right-left direction in the electronic device according to the comparative example. Therefore, in a case where the sensor 6 includes a strain sensor, the same effect as that of the electronic device 1 is obtained.

The polarity of an electric charge generated by the piezoelectric film 14 when the piezoelectric film 14 is stretched in the right-left direction may be the same as the polarity of an electric charge generated by the piezoelectric film 14 when the piezoelectric film 14 is stretched in the front-rear direction. More specifically, as illustrated in FIGS. 7 and 10, the amount of stretching of the piezoelectric film 14 in the right-left direction is larger than the amount of stretching of the piezoelectric film 14 in the right-left direction in the electronic device according to the comparative example, and thus the same effect as that of the electronic device 1 is obtained also in this case.

Note that the first adhesive member 7 may not have waterproofness.

Note that the two sides extending in the front-rear direction may be short sides, and the two sides extending in the right-left direction may be long sides.

Note that the sensor 6 may be disposed at a position other than the center of the first plate-shaped member 2 in the front-rear direction as viewed in the vertical direction.

The first plate-shaped member 2 may not be a transparent plate. The first plate-shaped member 2 may be, for example, a resin plate or a printed wiring board. The first plate-shaped member 2 may include a touch pad instead of the touch panel. In this case, the second plate-shaped member 4 and the second adhesive member 5 are unnecessary.

Note that the sensor 6 may not have the longitudinal direction extending in the right-left direction. The sensor 6 may have a longitudinal direction extending in the front-rear direction.

The second plate-shaped member 4 may not include the touch panel.

The first plate-shaped member 2 may not have a rectangular shape.

The second plate-shaped member 4 may not have a rectangular shape.

The first adhesive member 7 may not have an annular shape surrounding the first plate-shaped member 2 as viewed in the vertical direction.

The first adhesive member 7 may overlap at least one of the two short sides as viewed in the vertical direction.

Note that the electronic device 1 may further include a touch sensor that detects a position pressed by the user. In this case, the magnitude of a force with which the user presses the first plate-shaped member 2 can be calculated based on a detection signal output by the sensor 6 and the position detected by the touch sensor. As a result, according to the electronic device 1, the magnitude of the force with which the user presses the first plate-shaped member 2 can be detected more accurately.

The length of the long side of the substrate 16 may be the same as the lengths of the long side of the piezoelectric film 14, the long side of the upper electrode 15a, and the long side of the lower electrode 15b.

The length of the short side of the substrate 16 may be the same as the lengths of the short side of the piezoelectric film 14, the short side of the upper electrode 15a, and the short side of the lower electrode 15b.

### DESCRIPTION OF REFERENCE SYMBOLS

1: Electronic device
2: First plate-shaped member
3: Housing
4: Second plate-shaped member
5: Second adhesive member
6: Sensor
7: First adhesive member
14: Piezoelectric film
15a: Upper electrode
15b: Lower electrode
16: Substrate
18, 20: Adhesive layer
LS1: First lower main surface
LS2: Second lower main surface
LS3: Third lower main surface
Op: Opening
US1: First upper main surface
US2: Second upper main surface
US3: Third upper main surface

1. An electronic device comprising:
a housing;
a first plate-shaped member that has a first upper main surface and a first lower main surface that are arranged in a vertical direction, and is fixed to the housing such that a part of a body of a user or an operation member is capable of contacting the first upper main surface;
a sensor that detects deformation of the first plate-shaped member; and
a first adhesive member in at least a part of a region surrounding the first plate-shaped member as viewed in the vertical direction and which fixes the first lower main surface of the first plate-shaped member to the housing, wherein
the first adhesive member has a storage elastic modulus of 1 MPa to 20 MPa.

2. The electronic device according to claim 1, wherein the storage elastic modulus of the first adhesive member is 1 MPa to 5 MPa.

3. The electronic device according to claim 1, further comprising:
a second plate-shaped member that has a second upper main surface and a second lower main surface that are arranged in the vertical direction, and is fixed to the first lower main surface of the first plate-shaped member; and
a second adhesive member that fixes the second upper main surface of the second plate-shaped member to the first lower main surface of the first plate-shaped member, wherein
the storage elastic modulus of the first adhesive member is higher than a storage elastic modulus of the second adhesive member.

4. The electronic device according to claim 3, wherein the storage elastic modulus of the second plate-shaped member is higher than 0 Pa and 0.3 MPa or less.

5. The electronic device according to claim 1, wherein
the first plate-shaped member has a rectangular shape having two long sides extending in a front-rear direction and two short sides extending in a right-left direction as viewed in the vertical direction, and
the first adhesive member overlaps at least one of the two long sides as viewed in the vertical direction.

6. The electronic device according to claim 5, wherein the sensor is located at a center of the first plate-shaped member in the front-rear direction as viewed in the vertical direction.

7. The electronic device according to claim 1, wherein the sensor includes a piezoelectric film having a third upper main surface and a third lower main surface that are arranged in the vertical direction.

8. The electronic device according to claim 7, wherein a polarity of an electric charge generated by the piezoelectric film when the piezoelectric film is stretched in a right-left direction is different from a polarity of an electric charge generated by the piezoelectric film when the piezoelectric film is stretched in a front-rear direction.

9. The electronic device according to claim 1, wherein a material of the piezoelectric film comprises polylactic acid.

10. The electronic device according to claim 1, wherein the sensor has a longitudinal direction extending in a right-left direction.

11. The electronic device according to claim 1, wherein the sensor is a strain sensor.

12. The electronic device according to claim 1, wherein the first adhesive member has an annular shape surrounding a periphery of the first plate-shaped member as viewed in the vertical direction.

13. The electronic device according to claim 12, wherein the first adhesive member fixes a periphery of an opening of the housing to a vicinity of an outer edge of the first plate-shaped member.
